(19) United States
(12) Patent Application Publication
(10) Pub. No.: US 2009/0250110 A1
(43) Pub. Date: Oct. 8, 2009

(54) FORWARD SCATTERING NANOPARTICLE ENHANCEMENT METHOD AND PHOTO DETECTOR DEVICE

(75) Inventors: Edward T. Yu, San Diego, CA (US); Daniel Derkacs, La Jolla, CA (US)

Correspondence Address: GREER, BURNS & CRAIN, 300 S WACKER DR, 25TH FLOOR, CHICAGO, IL, 60606, US

(73) Assignee: THE REGENTS OF THE UNIVERSITY OF CALIFORNIA, Oakland, CA (US)

(21) Appl. No.: 12/307,991

(22) PCT Filed: Jul. 13, 2007
(86) PCT No.: PCT/US07/16036

§ 371 Date: Feb. 19, 2009

Related U.S. Application Data
(60) Provisional application No. 60/830,902, filed on Jul. 14, 2006.

(51) Int. Cl. H01L 31/0264

(52) U.S. Cl. 136/257; 136/258; 136/261

(57) ABSTRACT

In devices of the invention, forward scattering nanoparticles are sized and arranged with respect to a photo conversion material to forward scatter radiation that would otherwise be reflected away from the photo conversion material. In preferred embodiment devices, a highest percentage of the nanoparticles are sized such that their predominant characteristic is scattering as opposed to absorption. The nanoparticles forward scatter radiation into the photo conversion material that would otherwise be reflected. In preferred embodiments, the nanoparticles are metal nanoparticles, such as gold, silver, copper, or aluminum nanoparticles, and in other embodiments the nanoparticles are dielectric nanoparticles, e.g., silica, sized to predominately forward scatter radiation.

### FIELD

A field of the invention is energy conversion, namely radiation energy into electrical energy in photo detector devices, e.g., photovoltaic devices, solar cells, etc.

### BACKGROUND

Photo detector devices convert electromagnetic radiation, typically at optical (far-infrared to ultraviolet) frequencies, to electrical energy. Example photo detector devices include photovoltaic devices and solar cells. Generally, an active layer absorbs photons and creates electrical current. There are many uses for photodetector devices, including applications as detectors, optical electrical communication elements, power sources, etc. The mechanism for conversion in a typical photo detector device is often relatively inefficient. There is a general recognition in the art that it would be desirable to increase the efficiency of photo detector devices. There is continued research toward that goal.

Metallic nanoparticles have been embedded in the active layers of organic semiconductor photovoltaic devices to provide direct excitation of surface plasmon polariton resonances. The metallic nanoparticles embedded in organic semiconductor films results in changes in dielectric response or absorption. For example, O. Stenzel et al, Solar Energy Materials & Solar Cells 37, 337 (1995), report that Cu, Au, and Ag material was deposited as part of a CuPc absorbing structure and broad-band increases in absorption were observed. The material was reported to be clusters, but no direct evidence indicated that the metals were actually in cluster form, and the discussion of the mechanism involved, while mentioning the possibility of plasmon excitation, was speculative. For the relatively small clusters of uniform shape distribution described by Stenzel et al., it is unlikely that plasmon excitation would lead to the broad-band enhancement that was observed, and the largest enhancement would be in the high-energy region where solar radiation is much less intense. In a second article, similar device structures are produced and more information is provided about particle size. O. Stenzel et al, “The Incorporation of Metal-Clusters into Thin Organic-Dye Layers as a Method for Producing Strongly Absorbing Composite Layers—Δn Oscillator Model Approach to Resonant Metal Cluster Absorption,” J. Phys. D: Appl. Phys. 28, 2154 (1995). Phenomenological modeling/fitting was performed and mechanisms based on interband transitions plus plasmon excitation were discussed. However, there was little if any direct evidence of plasmon effects based on clear correlation of the wavelengths at which enhancement was observed with nanoparticle size and consequent plasmon wavelength.

In another publication, incorporation of metal clusters in a ZnPc-based structure was reported. M. Westphalen et al, “Metal cluster enhanced organic solar cells,” Solar Energy Materials & Solar Cells 61, 97 (2000). The enhancement mechanism in this publication was attributed to electron-hole pair excitation in the metal nanoparticle followed by transport of the resulting energetic electron into the organic semiconductor, rather than to plasmon excitation followed by absorption in the semiconductor. The embedding of nanoparticles into device material layers presents fabrication issues, and can have other unintended effects. The types of structures, materials, and thickness that can be used to incorporate metal particles and clusters is limited.

For inorganic solid-state semiconductors, work by Stuart and Hall demonstrated increased optical absorption and photocurrent generation in structures consisting of metallic nanoparticles separated by an insulating layer from a Si-on-insulator device structure. H. R. Stuart and D. G. Hall, “Absorption Enhancement in Silicon-on-Insulator Waveguides Using Metal Island Films,” Appl. Phys. Left. 69, 2327 (1996); “Island Size Effects in Nanoparticle-Enhanced Photodetectors,” Appl. Phys. Lett. 73, 3815 (1998); “Enhanced Dipole-Dipole Interaction Between Elementary Radiators Near a Surface,” Phys. Rev. Lett. 80, 5663 (1998). The enhancement effect consisted of the excitation of waveguided modes in the thin Si layer, resulting in greatly increased optical path length within the Si material. This effect is not expected to be applicable to bulk semiconductor structures, in which lateral waveguiding is unlikely to occur.

Earlier work by one of the present inventors discusses direct excitation of surface plasmon polariton modes in metallic nanoparticles and the consequent increase in the near-field electromagnetic field amplitude in a p-n junction photodiode and thin film semiconductor devices. D. Schaadt et al, “Enhanced Semiconductor Optical Absorption Via Surface Plasmon Excitation in Metal Nanoparticles,” Appl. Phys. Lett. 86, 063106 (2005). The concept described in the 2005 paper Schaadt et al invokes absorption of photons by the metal nanoparticles and makes use of the consequent increase in the electromagnetic near field for the absorption increase. To take advantage of the near field effect, the device discussed in the paper was a silicon pn junction device with a shallow junction of 80 nm. The shallow junction device was selected because the absorption mechanism of particles to increase the near-field electromagnetic field amplitude was utilized and believed key. This is effective only within several tens of nm of the particle, limiting the effect to a thin semiconductor layer immediately below the particles. In the 2005 Schaadt work, spherical Au nanoparticles with diameters of 50-100 nm were deposited on shallow junction (80 nm) crystalline Si pn junction photodiodes to increase the absorption of light over a broad spectral range via the interaction of the incident electromagnetic radiation with surface plasmon polariton modes in the nanoparticles. The largest surface densities of Au nanoparticles were for the 50 nm particles.

The near-field electromagnetic effect described in the Schaadt et al. 2005 paper is not applicable to bulk Si photovoltaic devices, as it would require design of devices in which absorption occurs predominantly very near the device surface. Shallow junction devices are generally not used in practical photo detector devices due to the deleterious effect of surface recombination. Efficiency in shallow junction devices is harmed by high rates of recombination of electron and hole pairs at a semiconductor surface, which significantly reduces electrical current that is produced. In the case of detectors, such recombination in shallow junction devices limits sensitivity. In the case of solar cells such recombination limits power output. In silicon devices, pn junctions are typically at least about 0.5 μm deep, with significantly smaller junction depths leading to high surface recombination, increased sheet resistance and other disadvantages for photo detector devices. Group III-V devices have the more efficient photon absorption mechanism, but junctions still are at least about 100 nm thick and are typically a few hundred nanometers deep for photo detector devices.

Solar cells are particular photo detector devices whose practical success depends upon the efficiency of photo conversion over a broad range of wavelengths corresponding to the solar radiation spectrum. The more current produced for a given radiation level, the better. Due to cost and fabrication issues, however, silicon is the favored material system for solar cells despite its lower photo conversion efficiency compared to Group III-V material systems. With silicon, there is still a need for additional energy conversion efficiency. One technique is to make very thick silicon to increase path-length. Making high purity silicon thick enough to permit addition radiation to be absorbed in the longer path-length and thereby generate sufficient energy conversion for practical use is difficult and expensive.

Another option that has been considered for solar cells is hydrogenated amorphous silicon (a-Si:H). These solar cells have been of long-standing interest as a thin-film, low-cost alternative to bulk crystalline Si cells. Compared to crystalline Si, a-Si:H offers a much larger absorption coefficient across much of the solar radiation spectrum, as selection rules that apply to optical transitions in periodic crystals are relaxed in amorphous materials. Thus, an a-Si:H film of thickness ˜500 nm absorbs sufficient sunlight to enable efficient solar cell operation, compared to thicknesses of several tens to hundreds of microns that are required for bulk crystalline Si devices. However, the high defect densities typically present in a-Si:H thin films limit the typical minority carrier diffusion lengths to ˜100 nm. Consequently, a-Si:H solar cells are generally fabricated using even thinner a-Si:H layers, resulting in reduced absorption of incident solar radiation. Limited efficiency, due mostly to insufficient material quality, and high cost of non-Si materials are the main reasons bulk Si currently dominates over all other materials for practical solar cell applications.

The various material systems used for photo detectors could all benefit from enhanced photo conversion. Solutions for enhancing efficiency of photo conversion that are practical and cost effective will have a substantial favorable impact on the utility of many devices and the widespread adoption of other devices.

### SUMMARY OF THE INVENTION

In devices of the invention, forward scattering nanoparticles are sized and arranged with respect to a photo conversion material to forward scatter radiation that would otherwise be reflected away from the photo conversion material. In preferred embodiment devices, a highest percentage of the nanoparticles are sized such that their predominant characteristic is scattering as opposed to adsorption. The nanoparticles forward scatter radiation into the photo conversion material that would otherwise be reflected. In preferred embodiments, the nanoparticles are metal nanoparticles, such as gold, silver, copper, or aluminum nanoparticles, and in other embodiments the nanoparticles are dielectric nanoparticles, e.g., silica, sized to predominately forward scatter radiation at the desired wavelengths.

A particular preferred embodiment device is a photo detector device formed of bulk photo conversion material and having a not shallow pn junction depth. Nanoparticles are sized and arranged to forward scatter incident radiation into the photo conversion material. For silicon, a not shallow pn junction depth is at least about 0.3-0.5 μm, and preferably one to a few microns. For Group III-V materials, a not shallow junction depth is at least 100 nm and preferably a couple to a few hundred nanometers. Another preferred embodiment device is a molecular material, e.g., organic molecules or polymer, photo detector device. It is difficult to fabricate anti-reflection coatings for such materials due to their low index of refraction, but using the forward scattering of metal nanoparticles according to the invention provides an anti-reflection effect and increases photo conversion efficiency. Amorphous hydrogenated silicon devices of the invention include metal nanoparticles that are sized and arranged to forward scatter incident radiation, permitting the use of thin a-Si:H layers with increased efficiency.

### BRIEF DESCRIPTION OF THE DRAWINGS

FIG. 1 is a schematic perspective view of a preferred embodiment a-Si:H photovoltaic device of the invention; FIG. 1 also includes example dimensions for an example laboratory prototype device having the basic structure shown in FIG. 1;

FIG. 2 shows J-V characteristics, and the corresponding power output, for an example prototype a-Si:H photovoltaic device structure in accordance with FIG. 1 without forward scattering Au nanoparticles and for the same device structure following Au nanoparticle deposition are indicated by the dashed and solid lines, respectively, in FIG. 2;

FIG. 3 shows the amplitude of a simulated electric field for an incident wave with λ=600 nm and effective particle density of 3.7×10⁸ cm⁻² for a device consistent with the FIG. 1 photovoltaic device;

FIG. 4 shows the calculated ratio Rₚ of |E₀|², integrated over the a-Si:H layer, for devices incorporating Au nanoparticles to that for reference devices without Au nanoparticles, as a function of particle density, computed for incident electromagnetic radiation at λ=600 nm; and

FIG. 5 shows a schematic cross section of a preferred embodiment bulk semiconductor photo detector device of the invention.

### DETAILED DESCRIPTION OF THE PREFERRED EMBODIMENTS

In devices of the invention, forward scattering nanoparticles are sized and arranged with respect to a photo conversion material to forward scatter radiation that would otherwise be reflected away from the photo conversion material. In preferred embodiment devices, a highest percentage of the nanoparticles are sized such that their predominant characteristic is scattering as opposed to absorption. The nanoparticles forward scatter radiation into the photo conversion material that would otherwise be reflected. In preferred embodiments, the nanoparticles are metal nanoparticles, such as gold, silver, copper, or aluminum nanoparticles, and in other embodiments the nanoparticles are dielectric nanoparticles, e.g., silica, sized to predominately forward scatter radiation.

A particular preferred embodiment device is a photo detector device formed of bulk photo conversion material and having a not shallow pn junction depth. Nanoparticles are sized and arranged to forward scatter incident radiation into the photo conversion material. For silicon, a not shallow pn junction depth is at least about 0.3-0.5 μm deep, and preferably one to a few microns. For Group III-V materials, a not shallow junction depth is at least 100 nm and preferably a couple to a few hundred nanometers. Another preferred embodiment device is a molecular material, e.g., organic molecules or polymer, photo detector device. It is difficult to fabricate anti-reflection coatings for such materials due to their low refractive index, but using the forward scattering of metal nanoparticles according to the invention provides an anti-reflection effect and increases photo conversion efficiency. Amorphous hydrogenated silicon devices of the invention include metal nanoparticles that are sized and arranged to forward scatter incident radiation, permitting the use of thin a-Si:H layers with increased efficiency.

A preferred device of the invention is a semi-conductor photo device including nanoparticles sized and arranged to forward scatter radiation into a photo conversion material layer or layers of the semi-conductor photovoltaic device. The nanoparticles in preferred embodiments are metal, e.g., gold, silver, or aluminum, and in other embodiments are dielectric, e.g., silica. The photon absorption layer(s) can be bulk semi-conductor layers, including silicon or Group III-V layers, hydrogenated amorphous silicon (a-Si:H), or organic molecules or polymers. A preferred method of the invention increases energy conversion efficiency in semiconductor-based photovoltaic devices by increasing absorption of incident photons through forward scattering of metallic nanostructures.

Embodiments of the invention include solar cells that achieve engineered enhancements in optical absorption, short-circuit current density, and energy conversion efficiency. At relatively modest nanoparticle densities, the invention provides increases in short-circuit current density and energy conversion efficiency under halogen lamp illumination in excess of 8%, with finite-element electromagnetic simulations and testing of prototype devices indicating that substantially larger efficiency increases are available with is higher nanoparticle densities.

Absorption is increased in devices of the invention by exploiting the dielectric behavior of metallic or other nanostructures at visible and near-visible wavelengths to induce forward-scattering of incident radiation and thus increased transmission of photons into the active semiconductor region of the photovoltaic device. The increased transmission of photons results in correspondingly increased optical absorption and photo generation of electrical current. The range of wavelengths within which this effect occurs can be controlled via the structure and composition of the nanostructures.

The nature of the forward scattering effect indicates that the increased efficiency is applicable to all semiconductor materials, including bulk materials such as bulk silicon. Experiments have been conducted and demonstrated increased efficiency for amorphous silicon thin-film photovoltaic devices under broad-spectrum visible illumination. The nature of the forward scatter physical effect will also produce increased energy conversion efficiency in both thin-film and bulk semiconductor photovoltaic devices fabricated in silicon or other semiconductor materials, e.g., the Group III-V materials and organic molecules or polymer materials.

The fundamental forward scattering mechanism of operation of embodiments of the invention suggest numerous device applications: In a thin-film semiconductor photovoltaic device, appropriate placement of metallic or dielectric nanoparticles in the path of incident radiation will lead to increased transmission of electromagnetic energy into the device, resulting in increased photocurrent generation and consequently increased energy conversion efficiency. Through the use of an optimized combination of nanoparticle shapes and/or sizes, enhanced absorption should be achieved over a large range of the incident solar radiation spectrum. In a bulk semiconductor photovoltaic device, appropriate placement of metallic or dielectric nanoparticles in the path of incident radiation will lead to increased transmission of electromagnetic energy into the device, resulting in increased photocurrent generation and consequently increased energy conversion efficiency while permitting use of a junction depth that is sufficient to avoid excessive rates of recombination or high sheet resistance.

The increase in optical transitions provided by the forward scattering mechanism persists to large distances (tens to possibly hundreds of microns) below the surface upon which radiation is incident. Through the use of an optimized combination of nanoparticle shapes and/or sizes, enhanced absorption could be achieved over a large range of the incident solar radiation spectrum. In a bulk semiconductor photodetector, appropriate placement of metallic or dielectric nanoparticles in the path of incident radiation will lead to increased transmission of electromagnetic energy into the device, resulting in increased photocurrent generation and consequently increased light sensitivity. Appropriate engineering of the nanoparticles could enable this increased sensitivity to be wavelength-dependent, enabling imaging of different wavelengths (colors) in different devices based on a single photodetector semiconductor structure.

Preferred embodiments will now be discussed with respect to the drawings. The drawings include schematic figures that are not to scale, which will be fully understood by skilled artisans with reference to the accompanying description. Features may be exaggerated for purposes of illustration. From the preferred embodiments, artisans will recognize additional features and broader aspects of the invention.

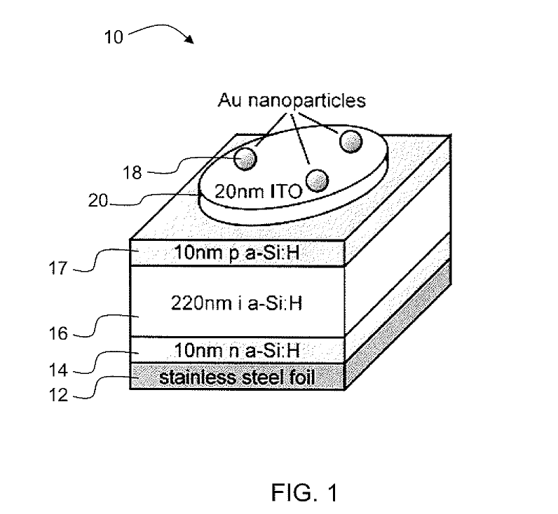

FIG. 1 is a schematic diagram of a preferred embodiment a-Si:H photovoltaic device 10 with enhanced efficiency from forward scattering metal nanoparticles. In addition to the basic device structure, FIG. 1 shows example materials and dimensions for layers from a prototype device. Artisans will appreciate that the example dimensions represent a preferred device and the invention is not limited thereto. Characteristics and performance of example laboratory prototype devices will be discussed along with broader aspects of the invention.

In FIG. 1, a substrate 12, such as a stainless steel foil acts as a bottom electrode. Carried on the substrate 12 is an a-Si:H p-i-n structure including a-Si:H p, intrinsic and n layers 14, 16, and 17, respectively. A top transparent electrode 20 is carried by the a-Si:H p-i-n structure. The top transparent electrode carries metal nanoparticles 22 arranged and in a density to produce forward scattering of incident electromagnetic radiation from the nanoparticles through the electrode and into the a-Si:H p-i-n structure. The metal nanoparticles in preferred embodiments are gold nanoparticles, and in other embodiments can be, for example, Ag, Al, or Cu. In other embodiments, the nanoparticles are dielectric nanoparticles, e.g., silica.

In selecting nanoparticles, different materials will have different sized nanoparticles that are suitable for forward scattering. At a certain diameter, depending upon the material of the particle, scattering becomes predominant over absorption. In devices of the invention, a substantial percentage, preferably the largest percentage, and more preferably a majority or substantially all of the nanoparticles are sized such that scattering predominates over absorption for wavelengths of interest. For example, with gold nanoparticles, at about 70 nm scattering becomes the dominant effect of the particles, and a preferred size is about 100 nm. Preferably, the largest percentage of particles used to forward scatter radiation are particles sized to predominately forward scatter light.

The dimensions shown in FIG. 1 represent a prototype laboratory device, and its fabrication will be discussed so that the performance results of the prototype can be appreciated and so that the forward scattering enhancement effect can be appreciated. For laboratory prototypes, 240 nm a-Si:H p-i-n structures were deposited by hot-wire chemical vapor deposition on stainless steel substrates. Contact patterns to the p-type surface were formed by optical lithography, followed by immersion in buffered oxide etch for 15 s to remove the surface oxide. A 20 nm indium tin oxide (ITO) contact layer was then deposited by RF sputtering for 3 min at 350° C., and a standard liftoff procedure was then employed to produce circular diodes 500 μm in diameter on a 5 mm×5 mm sample. Due to the short (˜100 nm) minority carrier diffusion length of a-Si:H, and the high sheet resistance of the p-layer, the active area of each diode was assumed to be equal to the ITO contact area. This assumption does not affect the relative changes in short-circuit current density and energy conversion efficiency discussed below, although the absolute current density levels may be affected. Photovoltaic devices fabricated from the same a-Si:H samples using thin partially transparent Pd metal contacts ˜15 nm in thickness yielded energy conversion efficiencies of approximately 5% under AM1.5 illumination.

In the fabrication of prototype devices, following deposition of the ITO contacts, the device surface was subjected to a 5 min exposure to a poly-L-lysine solution and then a 4 min exposure to a solution containing 100 nm Au colloidal nanoparticles, and then blown dry with N₂. A 5 min oxygen clean was then used to remove residual poly-L-lysine from the surface, leading to more direct contact between the nanoparticles and the underlying ITO layer. To increase the concentration of nanoparticles on the surface, this deposition procedure was repeated up to 5 times; and additional iterations typically resulted in clustering of nanoparticles on the surface. Scanning electron microscope (SEM) images, confirmed that predominantly isolated Au nanoparticles were present, with a surface concentration for the device discussed below of 3.7×10⁸ cm⁻¹.

Current density v. voltage (J-V) characteristics were measured using a Hewlett-Packard 4150a semiconductor parameter analyzer. The diodes were illuminated using a fiber optic lamp with a 30 watt quartz-halogen bulb, locked into position above the sample to provide illumination at normal incidence to the device surface. Samples were placed on the stage of a probe station and contacts were aligned by microscope beneath the light source to ensure precise and reproducible positioning of each diode under illumination during successive measurements. As references, J-V characteristics for each diode on each sample were first measured both in the dark and under illumination prior to nanoparticle deposition. Following these initial measurements, Au nanoparticles were deposited in the manner described above, and J-V measurements were performed on the resulting devices both in the dark and under illumination. J-V characteristics from 8 diodes spanning two samples were measured; standard deviations of only ˜0.1 mA/cm⁻² between diode J-V measurements were observed, and the J-V characteristics presented in this application represent averages across all diodes measured for each set of structures and measurement conditions.

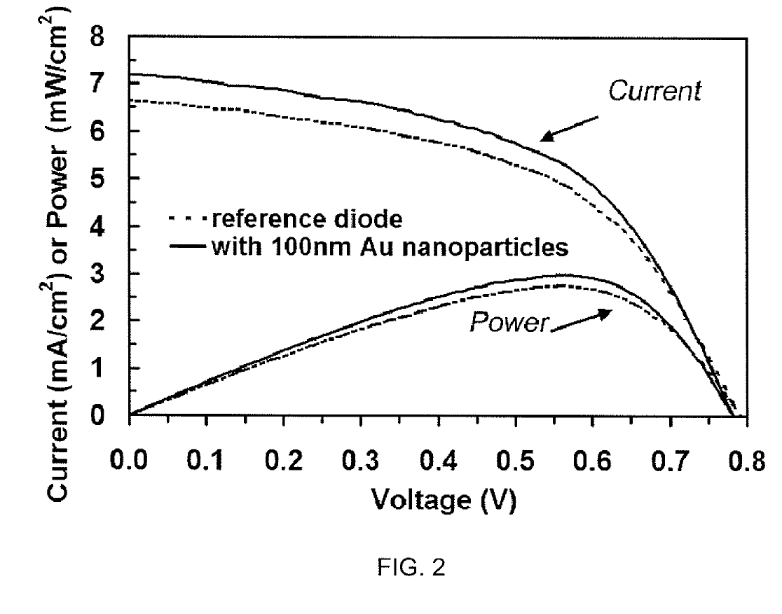

J-v characteristics, and the corresponding power output, for the reference device structure without Au nanoparticles and for the same device structure following Au nanoparticle deposition are indicated by the dashed and solid lines, respectively, in FIG. 2. An 8.1% increase in short-circuit (V=0) current density, from 6.66 mA/cm² to 7.20 mA/cm², and a 8.3% increase in power output (and consequently in energy conversion efficiency), from 2.77 mW/cm² to 3.00 mW/cm², are observed for the device structure in which Au nanoparticles of concentration 3.7×10⁸ cm⁻² have been incorporated. The different increases in short-circuit current density and energy conversion efficiency are a consequence of a slight increase in fill factor, from 52.6% to 52.8%, following nanoparticle deposition. Multiple cleanings performed as part of the nanoparticle deposition process can result in a rounding of the illuminated J-V curves, a decrease in short-circuit current density, typically by ˜3-5%, a substantial decrease in the open circuit voltage, and an increase in diode dark current, typically by a factor of 80-100. For example, a sample having a lower Au nanoparticle concentration of 1.75×10⁸ cm² undergoing a more rigorous clean yielded a 7.5% increase in short-circuit current density, from 6.85 mA/cm² to 7.35 mA/cm², but suffers from a decrease in the open circuit voltage, from 0.75V to 0.70V, a decrease in the fill factor, from 49.0% to 48.5%, and a 1.2% decrease in power output, from 2.52 mW/cm² to 2.49 mW/cm². Thus, the improvement in short-circuit current density and energy conversion efficiency arising specifically from the presence of the Au nanoparticles and their influence on distribution of electromagnetic field intensity may in fact be larger than the increase determined from the experimental measurements, but care in device processing must be exercised. Commercial fabrication facilities applying the principles of the invention should achieve larger enhancements.

These results can be explained through a combination of the well-known Mie theory for electromagnetic absorption and scattering by isolated spherical particles, and—to account for the more elaborate geometry of the devices studied here—computational electromagnetic simulations. As light of wavelength λ interacts with small (diameter d<<λ) metallic particles, extinction behavior due to resonant excitation of electron oscillations in the metal is observed as a distinct minimum in the transmission spectrum. For particles with diameter below ˜10 nm, only a single dipolar mode is supported; as the particle size increases, dipolar, quadrupolar, and other higher-order modes may be supported as well. Each supported mode may be described in terms of electric and magnetic partial waves emanating from the particle, with the electric partial waves resulting from the collective oscillation of conduction electrons—surface plasmon polaritons—giving rise to the particle's extinction characteristics.

The total Mie extinction is a sum of contributions from absorption and from scattering associated with each supported surface plasmon polariton mode of the particle. For small particles supporting only dipolar modes, the total extinction cross-section consists of a large absorption cross-section and a smaller scattering cross-section. For larger particles, with diameters of ˜100 nm or larger, the opposite is true: although the total extinction cross-section remains dominated by dipolar contributions, calculations have shown that the scattering cross-section is much larger than the absorption cross-section. In addition, scattering of incident light from large to particles in the visible spectrum at and above the Au nanoparticle resonant wavelength (˜500 nm) is predominantly in the forward direction.

The conclusion that visible light is forward scattered when incident on a single large nanoparticle is true in general for an ensemble of non-interacting particles suspended in a dielectric medium, and intuitively suggests that transmission of electromagnetic radiation into an appropriately positioned structure might be enhanced. However, for closely spaced particles on an absorbing substrate, particle-particle, particle-substrate, and particle-substrate-particle electromagnetic interactions complicate the propagation of the scattered field into the substrate.

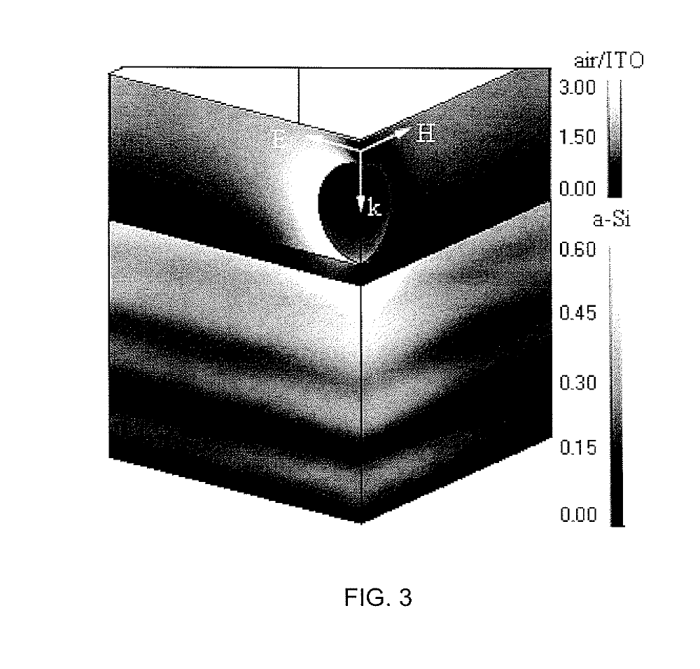

Finite-element electromagnetic simulations were performed using FEMLAB™ for the geometry shown in FIG. 3. Simulations were performed for device structures with and without 100 nm Au nanoparticles on top of a 20 nm ITO contact and a 240 nm a-Si:H substrate; the dielectric functions for a-Si:H and ITO were obtained from the literature. P and N layers were on the order of 10 nm and the intrinsic layer was about 200 nm. A reflective boundary condition was applied beneath the a-Si:H layer to model the stainless steel substrate. Quarter-plane symmetry was used for computational efficiency, and periodic boundary conditions were employed resulting in simulation of a periodic array of nanoparticles atop the ITO/a-Si:H thin-film structure. Transverse electromagnetic waves were launched from above the substrate and nanoparticle, if present, with wave vector normal to the substrate surface.

FIG. 3 shows the amplitude of the simulated electric field for an incident wave with λ=600 nm and effective particle density of 3.7×10⁸ cm⁻²—the same as that for the actual devices studied experimentally. Regions of high field amplitude are evident to the left of the particle (arising from the particle surface plasmon polariton resonance) and below the particle (arising from forward scattering of the incident wave). The dipole-like surface plasmon polariton resonance of the nanoparticle results in the enhanced electric field amplitude to the left of the nanoparticle, and as postulated we observe an enhanced electric field amplitude in the a-Si:H layer below the nanoparticle, which arises due to forward scattering of the incident wave by the nanoparticle. The oscillations visible in the a-Si:H are a consequence of the reflecting boundary created by the stainless steel substrate.

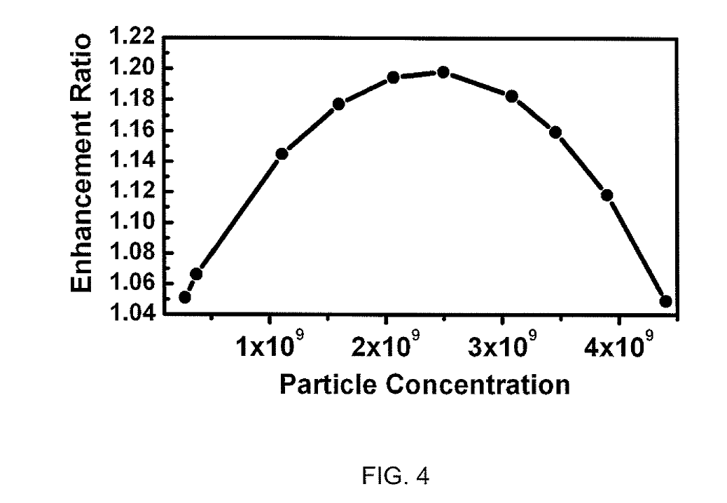

To estimate the influence of this field on the optical transition rate in the a-Si:H layer, and consequently on the photogenerated current, note that the optical transition rate is proportional to the square of the electric field amplitude, |E₀|². Thus, computation of the ratio Rₚ of |E₀|², integrated over the entire a-Si:H layer, for a structure with an Au nanoparticle present to that for a structure with no nanoparticle should provide a very approximate measure of the relative change in photogenerated current for light incident at a single wavelength due to the presence of the Au nanoparticle. FIG. 4 shows this ratio, derived from our simulations for an incident electromagnetic wave with wavelength 600 nm, as a function of Au nanoparticle density. Specifically, FIG. 4 shows the calculated ratio Rₚ of |E₀|², integrated over the a-Si:H layer, for devices incorporating Au nanoparticles to that for reference devices without Au nanoparticles, as a function of particle density, computed for incident electromagnetic radiation at λ=600 nm. While this relatively simple calculation does not provide a quantitative prediction of the corresponding increase in photogenerated current, it is clear that a substantially; larger increase than that observed in our experiments should be attainable at higher particle densities. At a wavelength of 600 nm, a particle density of approximately 2.5×10⁹ cm⁻² appears to be optimal, resulting in an increase in Rₚ approximately three times larger than that at the concentration present in the experiments. More generally, as seen in FIG. 4, substantially better performance is achieved in a range of about 1×10⁹ cm⁻² to 4×10⁹ cm⁻². In preferred embodiment devices, a substantial percentage, preferably the largest percentage, and more preferably a majority or substantially all of the nanoparticles are sized such that scattering predominates over absorption for wavelengths of interest. A further increase should be possible by integrating nanoparticles with an anti-reflection coating.

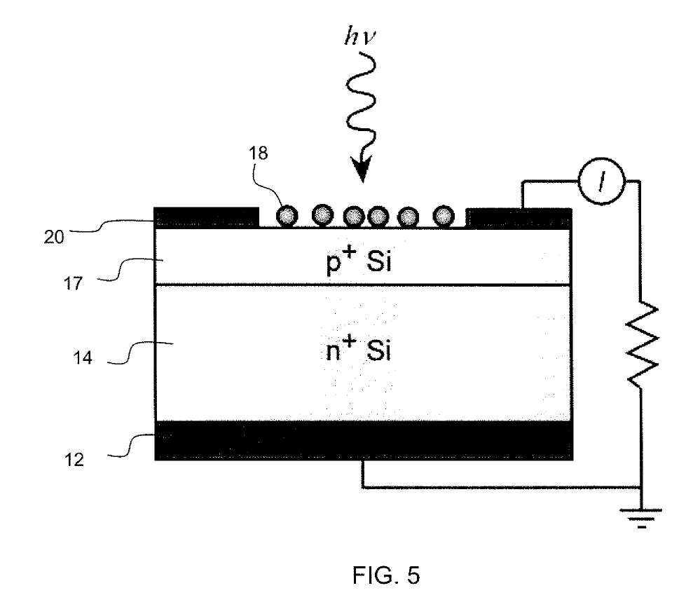

FIG. 5 shows a schematic cross section of a preferred embodiment bulk semiconductor photo detector device of the invention. Reference numbers from FIG. 1 have been used to identify comparable portions of the detector device shown in FIG. 5. The nanoparticles are sized, arranged and in a concentration for exploitation of forward scattering to increase optical absorption and photocurrent generation within the semiconductor consistent with the principles discussed above. The pn junction in the device is not shallow. In a silicon device (illustrated), the junction is at least about 0.5 μm, and is preferably one to a few microns. In a Group III-V device, the junction is at least about 100 nm and preferably a couple to a few hundred nanometers.

Because the process employed to deposit nanoparticles on the device surface decreases the measured photocurrent by ˜3-5%, the photocurrent enhancement attributable to the presence of the nanoparticles should actually be in the range of 11-13%. Based on numerical simulations it is anticipated that at higher particle concentrations, this enhancement could be increased by a factor of approximately three, i.e., the photocurrent could be increased by ˜40% at optimum particle concentration.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A photo detector device, the device comprising:
a photo conversion material for converting radiation into electrical energy;
within the path of radiation to the photo conversion material, nanoparticles shaped and arranged to forward scatter radiation into the photo conversion material, wherein a substantial percentage of the nanoparticles are sized such that scattering predominates over absorption for wavelengths of interest.

2. The device of claim 1, wherein a largest percentage of the nanoparticles are sized such that scattering predominates over absorption for wavelengths of interest.

3. The device of claim 1, wherein said photo conversion material comprises bulk semiconductor material, the device further comprising a not shallow pn junction in the bulk semiconductor material.

4. The device of claim 3, wherein the semiconductor material comprises bulk silicon and the not shallow pn junction is at least about 0.3 μm deep.

5. The device of claim 3, wherein the nanoparticles are metallic nanoparticles.

6. The device of claim 5, wherein said metallic nanoparticles have a density in the path of radiation in the range of 1×10⁹ cm⁻² to 4×10⁹ cm⁻².

7. The device of claim 6, wherein said metallic nanoparticles comprise gold nanoparticles.

8. The device of claim 7, wherein a largest percentage of said gold nanoparticles have a diameter of ˜100 nm.

9. The device of claim 1, comprising:
a substrate:
said photo conversion material comprising an amorphous hydrogenated silicon active structure for converting radiation into electrical energy carried by the substrate; and
electrodes for outputting electrical current from the amorphous hydrogenated silicon active structure.

10. The device of claim 9, wherein said electrodes include a transparent electrode contacting said amorphous hydrogenated silicon active structure, said transparent electrode being disposed within the path of radiation to the amorphous hydrogenated silicon active structure, said nanoparticles being carried by the transparent electrode.

11. The device of claim 10, wherein said substrate comprises another one of said electrodes.

12. The device of claim 10, wherein said transparent electrode comprises indium tin oxide.
